(19) United States
(12) Patent Application Publication
(10) Pub. No.: US 2026/0150358 A1
(43) Pub. Date: May 28, 2026

(54) SEMICONDUCTOR DEVICE

(71) Applicant: DENSO CORPORATION, Kariya-city (JP)

(72) Inventors: Keisuke HONYA, Kariya-city (JP); Shigeki TAKAHASHI, Kariya-city (JP); Tomoki AKAI, Kariya-city (JP)

(21) Appl. No.: 19/456,334

(22) Filed: Jan. 22, 2026

Related U.S. Application Data
(63) Continuation of application No. PCT/JP2024/026322, filed on Jul. 23, 2024.

(30) Foreign Application Priority Data
Jul. 25, 2023 (JP) 2023-121047

(51) Int. Cl. H10D 62/60; H10D 12/00; H10D 84/00; H10D 64/27

(52) U.S. Cl. CPC H10D 62/60; H10D 12/481; H10D 84/161; H10D 64/513

(57) ABSTRACT

In a semiconductor device, a base layer is an ion-implanted layer and is divided by a barrier region into a first base layer adjacent to a drift layer and a second base layer adjacent to a first surface of a semiconductor substrate. The second base layer has a peak position, where an impurity concentration of the second base layer is maximum, at a depth between an emitter region and the barrier region and different from both a boundary with the emitter region and a boundary with the barrier region. In a surface portion of the second base layer, a stabilization layer of a first conductivity type is disposed, together with a contact region. A first electrode is electrically connected to the contact region and the stabilization layer in a freewheeling diode region.

### CROSS REFERENCE TO RELATED APPLICATIONS

The present application is a continuation application of International Patent Application No. PCT/JP2024/026322 filed on July 23, 2024, which designated the U.S. and claimed the benefit of priority from Japanese Patent Application No. 2023-121047 filed on July 25, 2023. The entire disclosures of each of the above applications are incorporated herein by reference.

### TECHNICAL FIELD

The present disclosure relates to a semiconductor device.

### BACKGROUND

Conventionally, semiconductor devices are known, in which an insulated gate bipolar transistor (hereinafter referred to as IGBT) element having an insulated gate structure and a freewheeling diode (hereinafter referred to as FWD) element are formed on a common semiconductor substrate.

### SUMMARY

A semiconductor device according to an aspect of the present disclosure includes a semiconductor substrate having an IGBT region including an IGBT element and an FWD region including an FWD element. The semiconductor substrate includes a drift layer of a first conductivity type, a base layer of a second conductivity type disposed above the drift layer, a collector layer of the second conductivity type disposed on a side of the drift layer opposite the base layer in the IGBT region, and a cathode layer of the first conductivity type disposed on the side of the drift layer opposite the base layer in the FWD region. The semiconductor substrate has a first surface adjacent to the base layer and a second surface adjacent to the collector layer and the cathode layer. The semiconductor device further includes a barrier region of the first conductivity type, a trench gate structure, an emitter region of the first conductivity type, a contact region of the second conductivity type, a first electrode, and a second electrode. The barrier region is disposed within the base layer and divides the base layer into a first base layer adjacent to the drift layer and a second base layer adjacent to the first surface of the semiconductor substrate. The trench gate structure includes a trench penetrating the base layer and the barrier region into the drift layer in the IGBT region, a gate insulating film disposed on a wall surface of the trench, and a gate electrode disposed on the gate insulating film. The emitter region is disposed in a surface portion of the second base layer in the IGBT region and is in contact with the trench. The contact region is disposed in the surface portion of the second base layer in the FWD region and has a higher impurity concentration than the second base layer. The first electrode is disposed on the first surface of the semiconductor substrate and is electrically connected to the emitter region and the contact region. The second electrode is disposed on the second surface of the semiconductor substrate and is electrically connected to the collector layer and the cathode layer. The base layer is an ion-implanted layer. The second base layer has a peak position, where an impurity concentration of the second base layer is maximum, at a depth between the emitter region and the barrier region and different from both a boundary with the emitter region and a boundary with the barrier region. The semiconductor device may further include a stabilization layer of the first conductivity type disposed, together with the contact region, in the surface portion of the second base layer in the FWD region. The first electrode may be electrically connected to the contact region and the stabilization layer in the FWD region. The stabilization layer may have a lower impurity concentration than the emitter region.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of a semiconductor device according to a first embodiment;

FIG. 2 is a plan view of the semiconductor device shown in FIG. 1;

FIG. 3 is a perspective cross-sectional view of an FWD element;

FIG. 4 is a diagram showing a relationship between a depth of a semiconductor substrate and a P-type impurity concentration;

FIG. 5 is a diagram showing a relationship between a forward voltage and a forward current of the FWD element and a surface concentration of a stabilization layer;

FIG. 6 is a plan view of a semiconductor device according to a second embodiment;

FIG. 7 is a diagram showing a relationship between a collector-emitter voltage and a collector current of an IGBT element and a surface concentration of a stabilization layer; and

FIG. 8 is a diagram showing a relationship between a gate-emitter voltage and a collector current of the IGBT element and a peak position of the stabilization layer.

### DETAILED DESCRIPTION

Next, relevant technology is described to facilitate understanding of the following embodiments. A semiconductor device having an IGBT element is configured such that a base layer of P-type is disposed on a drift layer of N-type, and an emitter region of N-type is formed in a surface portion of the base layer. In this semiconductor device, in order to suppress the inflow of holes (that is, carriers) from the drift layer to the base layer when the IGBT region is in the on-state, a barrier region of N-type that divides the base layer in the thickness direction is provided within the base layer.

Furthermore, in this semiconductor device, the base layer is formed as an ion-implanted layer in which P-type impurity ions have been implanted. In the base layer, a portion close to the drift layer is defined as a first base layer, and a portion located on the opposite side of the barrier region from the first base layer is defined as a second base layer. Specifically, the base layer has a configuration described below. The first base layer is configured such that a first peak position at which the concentration of P-type impurity is at its maximum is located between the barrier region and the drift layer. The second base layer is configured such that a second peak position at which the concentration of P-type impurity is at its maximum, is located between the emitter region and the barrier region. It should be noted that the first peak position is adjusted to be at a location different from the boundary between the barrier region and the drift layer, and, for example, is adjusted to be approximately at the center between the barrier region and the drift layer. The second peak position is adjusted to be at a location different from the boundary between the emitter region and the barrier region, and, for example, is adjusted to be approximately at the center between the emitter region and the barrier region.

The present inventors have been investigating a semiconductor device having a so-called Reverse Conducting (RC) IGBT structure, in which the IGBT element and the FWD element are formed on a common semiconductor substrate. Furthermore, the present inventors have been considering configuring the base layer in the FWD element in the same manner as that in the IGBT element, in order to simplify the manufacturing process. In this semiconductor device, the base layer, the emitter region, and the like are formed on a first surface side of the semiconductor substrate.

In this case, when the second peak position of the second base layer is adjusted as described above, since the base layer is formed as an ion-implanted layer, the portion of the second base layer that constitutes the first surface of the semiconductor substrate has an impurity concentration that gradually decreases from the second peak position, and the impurity concentration tends to vary easily. Therefore, in the FWD element, the forward voltage may vary.

A semiconductor device according to an aspect of the present disclosure includes a semiconductor substrate having an IGBT region including an IGBT element and an FWD region including an FWD element. The semiconductor substrate includes a drift layer of a first conductivity type, a base layer of a second conductivity type disposed above the drift layer, a collector layer of the second conductivity type disposed on a side of the drift layer opposite the base layer in the IGBT region, and a cathode layer of the first conductivity type disposed on the side of the drift layer opposite the base layer in the FWD region. The semiconductor substrate has a first surface adjacent to the base layer and a second surface adjacent to the collector layer and the cathode layer. The semiconductor device further includes a barrier region of the first conductivity type, a trench gate structure, an emitter region of the first conductivity type, a contact region of the second conductivity type, a stabilization layer of the first conductivity type, a first electrode, and a second electrode. The barrier region is disposed within the base layer and divides the base layer into a first base layer adjacent to the drift layer and a second base layer adjacent to the first surface of the semiconductor substrate. The trench gate structure includes a trench penetrating the base layer and the barrier region into the drift layer in the IGBT region, a gate insulating film disposed on a wall surface of the trench, and a gate electrode disposed on the gate insulating film. The emitter region is disposed in a surface portion of the second base layer in the IGBT region and is in contact with the trench. The contact region is disposed in the surface portion of the second base layer in the FWD region and has a higher impurity concentration than the second base layer. The stabilization layer is disposed, together with the contact region, in the surface portion of the second base layer in the FWD region. The first electrode is disposed on the first surface of the semiconductor substrate and is electrically connected to the emitter region and the contact region. The second electrode is disposed on the second surface of the semiconductor substrate and is electrically connected to the collector layer and the cathode layer. The base layer is an ion-implanted layer. The second base layer has a peak position, where an impurity concentration of the second base layer is maximum, at a depth between the emitter region and the barrier region and different from both a boundary with the emitter region and a boundary with the barrier region. The first electrode is electrically connected to the contact region and the stabilization layer in the FWD region.

According to the above-described configuration, the FWD region is configured such that the first surface of the semiconductor substrate, which is connected to the first electrode, includes the stabilization layer of the first conductivity type, and the first electrode is electrically connected to both the contact region and the stabilization layer. Therefore, compared to a case where the first surface of the semiconductor substrate in the FWD region is composed only of the contact region and the second base layer, the proportion of the second base layer, which is prone to have variations in impurity concentration, can be reduced on the first surface of the semiconductor substrate, thereby suppressing variations in the forward voltage of the FWD element.

The following describes embodiments of the present disclosure with reference to the drawings. In the following embodiments, the same or equivalent parts are denoted by the same reference numerals.

### First Embodiment

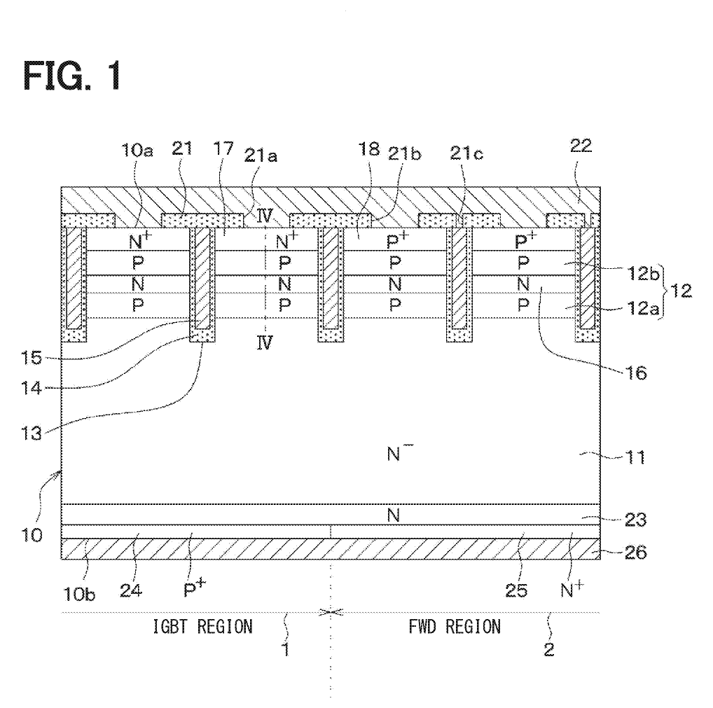

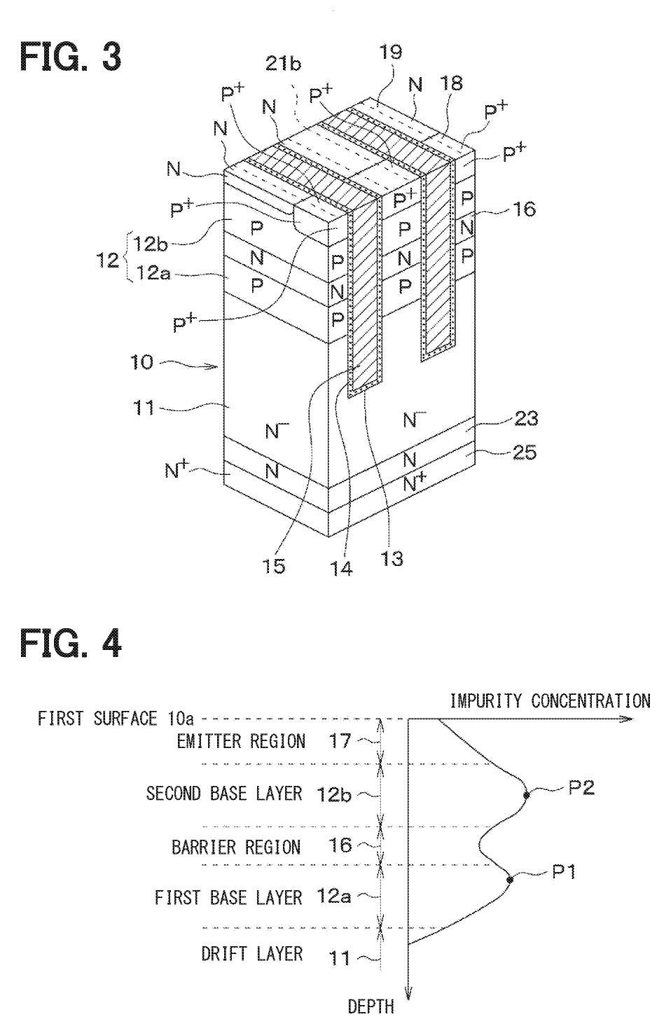

A semiconductor device according to a first embodiment will be described with reference to FIGS. 1 to 4. The semiconductor device according to the present embodiment is preferably used as a power switching element used in power supply circuits such as inverters and DC/DC converters, for example.

The semiconductor device has an IGBT region 1, which operates as an IGBT element, and an FWD region 2, which is disposed adjacent to the IGBT region 1 and operates as an FWD element. In other words, the semiconductor device of the present embodiment is an RC-IGBT in which the IGBT region 1 and the FWD region 2 are formed within a common semiconductor substrate 10, which will be described later. Specifically, as will be described later, in the present embodiment, a portion on a collector layer 24 located on a second surface 10b of the semiconductor substrate 10 operates as the IGBT region 1, and a portion on a cathode layer 25 located on the second surface 10b of the semiconductor substrate 10 operates as the FWD region 2.

The semiconductor device includes the semiconductor substrate 10 including a drift layer 11 of N⁻-type. Above the drift layer 11, a base layer 12 of P-type is disposed. Hereinafter, a surface of the semiconductor substrate 10 adjacent to the base layer 12 is referred to as a first surface 10a, and a surface of the semiconductor substrate 10 on the opposite side of the first surface 10a is referred to as a second surface 10b. The semiconductor substrate 10 is composed of, for example, silicon or the like.

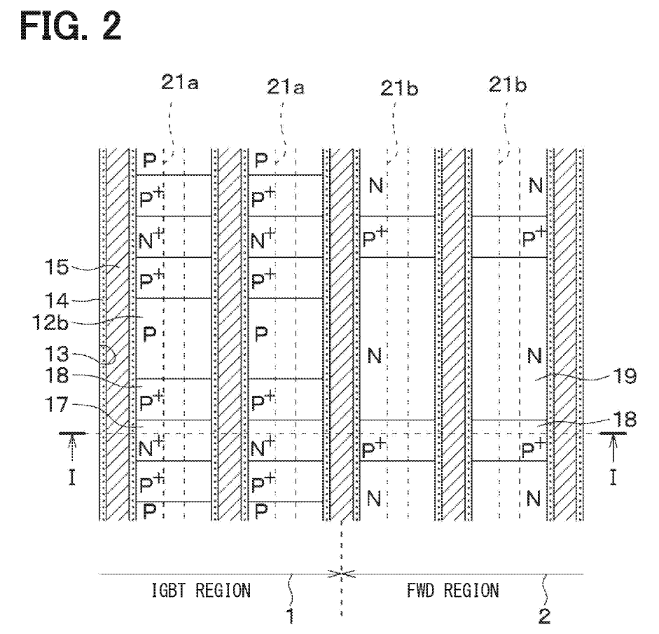

In the semiconductor substrate 10, a plurality of trenches 13 are formed from the first surface 10a so as to penetrate through the base layer 12 and reach the drift layer 11. As a result, the base layer 12 is divided into a plurality of sections by the trenches 13. In the present embodiment, the plurality of trenches 13 are formed in each of the IGBT region 1 and the FWD region 2. In the present embodiment, the trenches 13 are formed in a striped shape, with their longitudinal direction intersecting the arrangement direction of the IGBT region 1 and the FWD region 2 (that is, in a direction perpendicular to the plane of the page in FIG. 1). Hereinafter, the longitudinal direction of the trenches 13 may simply be referred to as the longitudinal direction, and in FIG. 2, the vertical direction of the page corresponds to the longitudinal direction. The spacing between adjacent trenches 13 (that is, the pitch) is, for example, set to approximately 2 μm.

Each of the trenches 13 is provided with a gate insulating film 14 formed so as to cover a wall surface of each of the trenches 13, and a gate electrode 15 made of polysilicon or the like formed on the gate insulating film 14. Accordingly, a trench gate structure is formed.

The gate electrodes 15 disposed in the trenches 13 in the IGBT region 1 are connected to a drive circuit (not shown) via gate wiring (not shown). The gate electrodes 15 disposed in the IGBT region 1 are applied with a predetermined pulsed gate voltage. In addition, the gate electrodes 15 disposed in the trenches 13 in the FWD region 2 are electrically connected to an upper electrode 22, which will be described later, and are maintained at a predetermined potential.

In the base layer 12, a barrier region 16 of N-type having a higher impurity concentration than the drift layer 11 is disposed so as to divide the base layer 12 in the depth direction of the semiconductor substrate 10. Hereinafter, a portion of the base layer 12 adjacent to the drift layer 11 is also referred to as a first base layer 12a, and a portion of the base layer 12 adjacent to the first surface 10a of the semiconductor substrate 10 is also referred to as a second base layer 12b. It should be noted that the base layer 12 in the IGBT region 1 and the base layer 12 in the FWD region 2 have the same structure.

Then, in a surface portion of the second base layer 12b, an emitter region 17 of N⁺-type, which has a higher impurity concentration than the drift layer 11, and a contact region 18 of P⁺-type, which has a higher impurity concentration than the base layer 12, are disposed in the IGBT region 1. In the present embodiment, the emitter region 17 and the contact region 18 are disposed so that portions of the surface portion of the second base layer 12b remain. That is, in the IGBT region 1, the emitter region 17 and the contact region 18 are disposed so that the first surface 10a of the semiconductor substrate 10 includes the second base layer 12b, the emitter region 17, and the contact region 18. In the present embodiment, in the IGBT region1, the emitter region 17 and the contact region 18 are disposed such that the contact region 18, the emitter region 17, the contact region 18, and the second base layer 12b are arranged repeatedly in this order along the longitudinal direction between the adjacent trenches 13.

In addition, in the surface portion of the base layer 12, a contact region 18 of P⁺-type, which has a higher impurity concentration than the base layer 12, is disposed in the FWD region 2. It should be noted that the contact region 18 in the FWD region 2 has the same configuration as the contact region 18 in the IGBT region 1. Furthermore, in the surface portion of the base layer 12, a stabilization layer 19 of N-type is disposed in the FWD region 2. In the present embodiment, the first surface 10a of the semiconductor substrate 10 in the FWD region 2 includes the contact region 18 and the stabilization layer 19. That is, in the FWD region 2 of the present embodiment, the stabilization layer 19 is disposed over the entire region of the first surface 10a of the semiconductor substrate 10 except for a region where the contact region 18 is disposed.

In the present embodiment, the length of the contact region 18 along the longitudinal direction in the FWD region 2 is made shorter than the length of the contact region 18 along the longitudinal direction in the IGBT region 1. However, the length of the contact region 18 along the longitudinal direction in the FWD region 2 and the length of the contact region 18 along the longitudinal direction in the IGBT region 1 can be appropriately modified as needed. For example, in the FWD region 2, when the length of the contact region 18 along the longitudinal direction increases, the forward voltage Vf when the FWD element operates as a diode decreases.

In the present embodiment, the first base layer 12a and the second base layer 12b are ion-implanted layers formed by implanting P-type impurity ions into the semiconductor substrate 10, and then diffusing the P-type impurity ions. The second base layer 12b is formed such that, as shown in FIG. 4, a second peak position P2 at which the impurity concentration of the second base layer 12b is at its maximum exists between the emitter region 17 and the barrier region 16. The first base layer 12a is formed such that a first peak position P1 at which the impurity concentration of the first base layer 12a is at its maximum exists between the barrier region 16 and the drift layer 11.

It should be noted that FIG. 4 shows the relationship between the concentration of the P-type impurity and the depth from the first surface 10a of the semiconductor substrate 10 along the section taken along line IV-IV in FIG. 1. In addition, the first peak position P1 is adjusted to a position different from the boundary between the first base layer 12a and the barrier region 16 or the drift layer 11, and, for example, is adjusted to a position that is approximately in the center between the barrier region 16 and the drift layer 11. The second peak position P2 is adjusted to a position different from the boundary between the second base layer 12b and the emitter region 17 or the barrier region 16, and, for example, is adjusted to a position that is approximately in the center between the emitter region 17 and the barrier region 16. By forming the first base layer 12a and the second base layer 12b in this manner, even if the thickness (that is, the position) of the emitter region 17 or the thickness (that is, the position) of the barrier region 16 slightly changes due to manufacturing errors or the like, the maximum impurity concentration of the first base layer 12a and the second base layer 12b will be at each respective peak position P1 and P2. Therefore, it is possible to suppress variations in the threshold voltage Vth. In addition, although not shown in the drawings, the emitter region 17, the barrier region 16, and the drift layer 11 are overall of N-type, since their corresponding portions are set to have an N-type impurity concentration higher than the P-type impurity concentration.

On the first surface 10a of the semiconductor substrate 10, an interlayer insulating film 21 composed of borophosphosilicate glass (BPSG) or the like is disposed. The interlayer insulating film 21 has contact holes 21a in the IGBT region 1 to expose the emitter region 17, the contact region 18, and the second base layer 12b. The interlayer insulating film 21 has contact holes 21b in the FWD region 2 to expose the contact region 18 and the stabilization layer 19.

An upper electrode 22 is disposed on the interlayer insulating film 21 in the IGBT region 1 and is electrically connected to the emitter region 17, the contact region 18, and the second base layer 12b through the contact holes 21a formed in the interlayer insulating film 21. The upper electrode 22 is also disposed on the interlayer insulating film 21 in the FWD region 2 and is electrically connected to the contact region 18 and the stabilization layer 19 through the contact holes 21b formed in the interlayer insulating film 21. In other words, the upper electrode 22 is disposed on the interlayer insulating film 21 to function as an emitter electrode in the IGBT region 1 and an anode electrode in the FWD region 2.

In the present embodiment, the upper electrode 22 forms ohmic contacts with the emitter region 17 and the contact region 18, and forms a Schottky contact with the second base layer 12b.

In addition, in the present embodiment, the interlayer insulating film 21 has contact holes 21c in the FWD region 2 to expose the gate electrodes 15. Then, the upper electrode 22 is also connected to the gate electrodes 15 through the contact holes 21c. Accordingly, the gate electrodes 15 disposed in the FWD region 2 are maintained at the same potential as the upper electrode 22. It should be noted that, in the present embodiment, the upper electrode 22 corresponds to a first electrode.

On a side of the drift layer 11 opposite the base layer 12 (that is, on a side of the drift layer 11 close to the second surface 10b of the semiconductor substrate 10), a field stop layer (hereinafter simply referred to as the FS layer) 23 of N-type having a higher impurity concentration than the drift layer 11 is disposed. The FS layer 23 is not necessarily required, but it is provided to improve breakdown voltage and steady-state loss performance by preventing the expansion of the depletion layer, as well as to control the amount of holes injected from the second surface 10b of the semiconductor substrate 10.

Then, in the IGBT region 1, a collector layer 24 of P⁺-type is disposed on a side opposite the drift layer 11 across the FS layer 23, and in the FWD region 2, a cathode layer 25 of N⁺-type is disposed on the side opposite the drift layer 11 across the FS layer 23. In other words, the IGBT region 1 and the FWD region 2 are distinguished by whether the layer disposed on the second surface 10b of the semiconductor substrate 10 is the collector layer 24 or the cathode layer 25. Thus, the region above the collector layer 24 is defined as the IGBT region 1, and the region above the cathode layer 25 is defined as the FWD region 2.

On the side opposite the drift layer 11, a lower electrode 26 electrically connected to the collector layer 24 and the cathode layer 25 is disposed across the collector layer 24 and the cathode layer 25 (that is, on the second surface 10b of the semiconductor substrate 10). In other words, the lower electrode 26 is disposed so as to function as a collector electrode in the IGBT region 1 and as a cathode electrode in the FWD region 2. In the present embodiment, the lower electrode 26 forms ohmic contacts with the collector layer 24 and the cathode layer 25. In the present embodiment, the lower electrode 26 corresponds to a second electrode.

By being configured in this manner, the semiconductor device of the present embodiment forms an IGBT element in the IGBT region 1, in which the base layer 12 and the contact region 18 operate as a base, the emitter region 17 operates as an emitter, and the collector layer 24 operates as a collector. Additionally, in the FWD region 2, an FWD element is formed in which the base layer 12 and the contact region 18 operate as an anode, the drift layer 11, the FS layer 23, and the cathode layer 25 operate as a cathode, and the anode and the cathode form a PN junction.

The configuration of the semiconductor device according to the present embodiment has been described above. In the present embodiment, the N-type, the N⁺-type, and the N⁻- type correspond to a first conductive type, and the P-type and P⁺-type correspond to a second conductive type. Furthermore, in the present embodiment, by being configured as described above, the semiconductor substrate 10 includes the collector layer 24, the cathode layer 25, the drift layer 11, the base layer 12, the barrier region 16, the emitter region 17, the contact region 18, the stabilization layer 19, and the like.

Next, while explaining the operation of the semiconductor device, the detailed configuration of the semiconductor device will be further described.

In the semiconductor device described above, when a voltage higher than that of the upper electrode 22 is applied to the lower electrode 26, the PN junction formed between the base layer 12 and the drift layer 11 enters a reverse conduction state, resulting in the formation of a depletion layer. Then, when a low-level gate voltage (for example, 0 V), which is below a threshold voltage Vth of the insulated gate structure, is applied to the gate electrodes 15, no collector current flows between the upper electrode 22 and the lower electrode 26.

In order to turn on the IGBT element, a high-level gate voltage equal to or greater than the threshold voltage Vth of the insulated gate structure is applied to the gate electrodes 15 of the IGBT region 1, while a voltage higher than that of the upper electrode 22 is applied to the lower electrode 26. As a result, in the IGBT region 1, inversion layers are formed in portions of the base layer 12 that are in contact with the trenches 13. Then, in the IGBT element, electrons are supplied from the emitter region 17 to the drift layer 11 via the inversion layers, and as a result, holes are supplied from the collector layer 24 to the drift layer 11. As a result, in the IGBT element, the conductivity modulation lowers the resistance of the drift layer 11, allowing collector current to flow between the upper electrode 22 and the lower electrode 26.

At this time, in the present embodiment, the barrier region 16 makes it difficult for the holes supplied to the drift layer 11 to escape to the base layer 12. Therefore, it is possible to reduce the on-voltage.

When the IGBT element is turned to the off-state and the FWD element is turned to the on-state (that is, the FWD element is operated as a diode), the voltage applied between the upper electrode 22 and the lower electrode 26 is switched, and a forward bias is applied by applying a higher voltage to the upper electrode 22 than to the lower electrode 26. As a result, holes are supplied to the base layer 12 and electrons are supplied to the cathode layer 25, causing the FWD element to operate as the diode.

At this time, in the present embodiment, in the FWD region 2, the first surface 10a of the semiconductor substrate 10 includes the contact region 18 of P-type and the stabilization layer 19 of N-type. In other words, in the FWD region 2, the second base layer 12b, whose impurity concentration is likely to vary, is not exposed on the first surface 10a of the semiconductor substrate 10, and the upper electrode 22 is not in contact with the second base layer 12b. Therefore, the forward voltage Vf of the FWD element depends on the contact region 18. Accordingly, variation in the forward voltage Vf of the FWD element can be suppressed.

In the present embodiment, in the IGBT region 1, the second base layer 12b is exposed on the first surface 10a of the semiconductor substrate 10, and the second base layer 12b forms a Schottky contact with the upper electrode 22. Therefore, for example, compared to a semiconductor device in which this portion of the second base layer 12b operates as the contact region 18, the number of holes that can be injected into the second base layer 12b of the IGBT region 1 when the FWD element is in the on-state can be reduced. Accordingly, when the voltage between the upper electrode 22 and the lower electrode 26 is switched to reverse bias, hole injection is suppressed, making it possible to reduce the recovery current and shorten the recovery time. Therefore, a switching loss can be reduced.

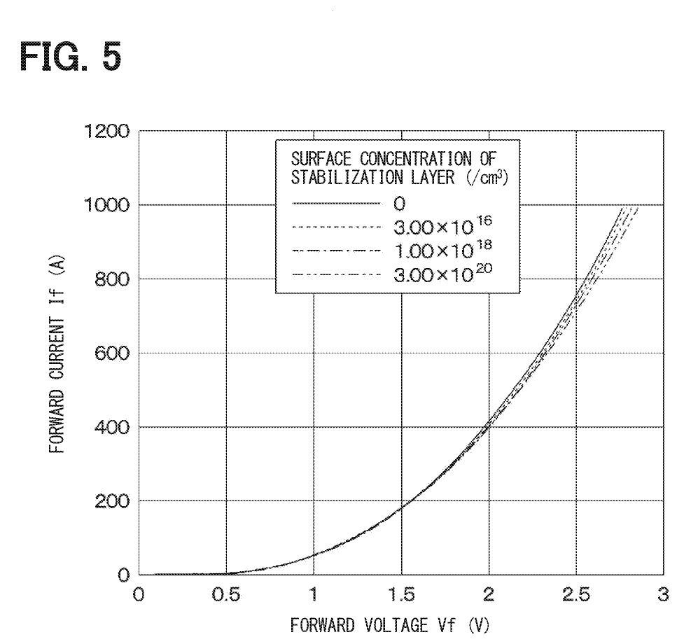

Furthermore, the present inventors conducted further intensive studies regarding the stabilization layer 19 and obtained the following results. As shown in FIG. 5, it has been confirmed that the forward voltage Vf of the FWD element increases with an increase in the surface concentration of the stabilization layer 19. Therefore, it is preferable that the surface concentration of the stabilization layer 19 be appropriately adjusted according to the application. Here, the surface concentration of the stabilization layer 19 refers to the concentration of the N-type impurity in the stabilization layer 19 at the first surface 10a of the semiconductor substrate 10.

According to the above-described embodiment, the FWD region 2 is configured such that the first surface 10a of the semiconductor substrate 10, which is connected to the upper electrode 22, includes the stabilization layer 19 of N-type. The upper electrode 22 is electrically connected to the contact region 18 and the stabilization layer 19. Therefore, compared to a case where the first surface 10a of the semiconductor substrate 10 in the FWD region 2 includes the contact region 18 and the second base layer 12b, the proportion of the second base layer 12b, which is prone to variations in impurity concentration at the first surface 10a of the semiconductor substrate 10, can be reduced, thereby suppressing variations in the forward voltage Vf of the FWD element.

In the present embodiment, the FWD region 2 is configured such that the first surface 10a of the semiconductor substrate 10 includes the contact region 18 and the stabilization layer 19. Therefore, the upper electrode 22 no longer comes into direct contact with the second base layer 12b, and variations in the forward voltage Vf of the FWD element can be further suppressed.

### Second Embodiment

The following describes a second embodiment of the present disclosure. The present embodiment is different from the first embodiment in that the stabilization layer 19 is also disposed in the IGBT region 1. The other configurations of the present embodiment are similar to those of the first embodiment, and therefore a description of the similar configurations will be omitted.

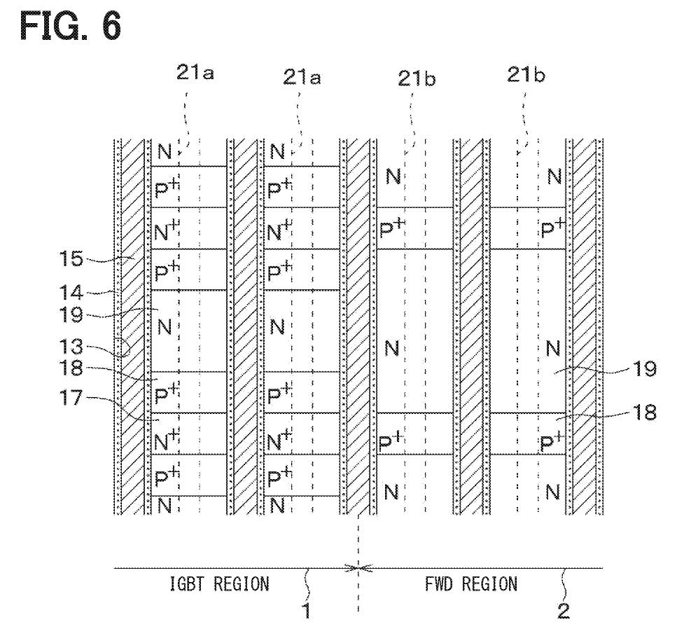

As shown in FIG. 6, in the semiconductor device of the present embodiment, the stabilization layer 19 is disposed in the surface portion of the second base layer 12b, along with the emitter region 17 and the contact region 18. Then, the first surface 10a of the semiconductor substrate 10 in the IGBT region 1 includes the emitter region 17, the contact region 18, and the stabilization layer 19. Specifically, in the IGBT region 1, the contact region 18, the emitter region 17, the contact region 18, and the stabilization layer 19 are arranged repeatedly in this order along the longitudinal direction between the adjacent trenches 13. In other words, in the IGBT region 1 of the present embodiment, the stabilization layer 19 is disposed at portions of the first surface 10a of the semiconductor substrate 10 where the second base layer 12b is exposed in the first embodiment. It should be noted that the stabilization layer 19 has a lower impurity concentration than the contact region 18.

The above describes the configuration of the semiconductor device in the present embodiment. The stabilization layer 19 in the semiconductor device described above can be formed as follows. That is, the stabilization layer 19 is formed by implanting N-type impurity ions into the surface portion of the second base layer 12b after the emitter region 17 and the contact region 18 have been formed. In this case, since the impurity concentration of the stabilization layer 19 is lower than that of the contact region 18, even if N-type impurity ions are implanted without placing a mask, the contact region 18 will not be converted to N-type. Therefore, in the present embodiment, by forming the stabilization layer 19 also in the IGBT region 1, the stabilization layer 19 can be formed by implanting N-type impurity ions without placing a mask, thereby simplifying the manufacturing process.

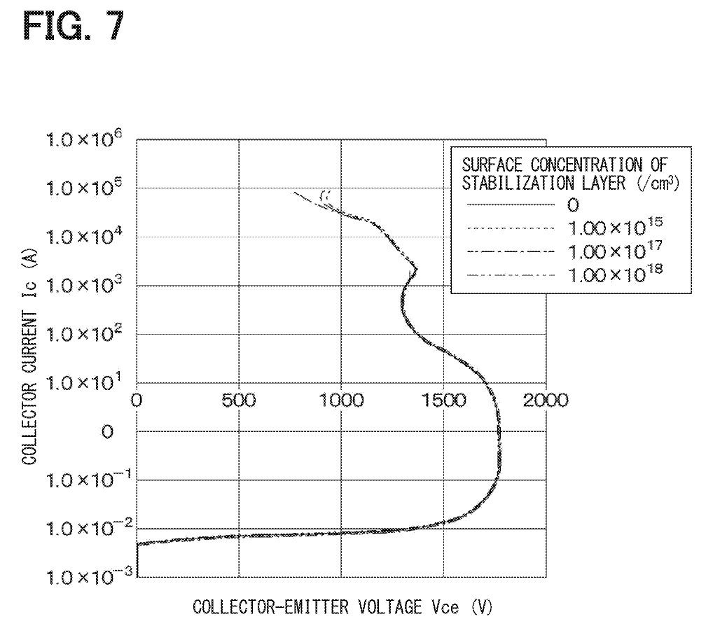

When the stabilization layer 19 is disposed in the IGBT region 1, since the stabilization layer 19 is N-type, there is a concern that latch-up tolerance may decrease due to the increase in the N-type layer. However, according to studies conducted by the present inventors, results as shown in FIG. 7 were obtained regarding the relationship between the collector-emitter voltage Vce, the collector current Ic, and the surface concentration of the stabilization layer 19. It should be noted that FIG. 7 shows the results obtained when the surface concentration of the emitter region 17 is set to 2.0×10²⁰ /cm³.

As shown in FIG. 7, it is confirmed that when the surface concentration of the stabilization layer 19 is lower than that of the emitter region 17, the latch-up current hardly changes. Therefore, in order to suppress a decrease in latch-up tolerance, it is preferable that the stabilization layer 19 has a lower impurity concentration than the emitter region 17.

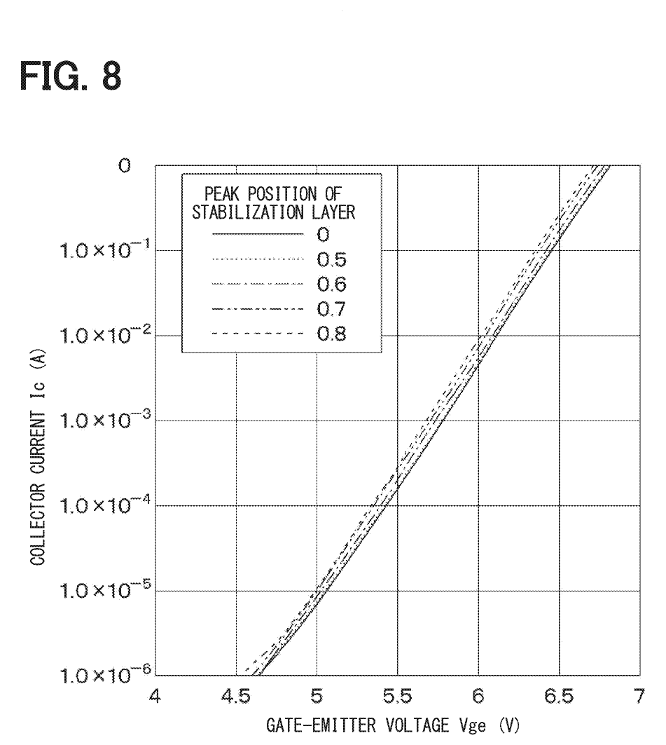

In addition, when the stabilization layer 19 is disposed in the IGBT region 1, there is a possibility that the stabilization layer 19 may affect the threshold voltage Vth (that is, the gate-emitter voltage Vge) of the IGBT element. According to studies conducted by the present inventors, the results shown in FIG. 8 were obtained regarding the relationship between the gate-emitter voltage Vge, the collector current Ic, and the peak position of the stabilization layer 19. It should be noted that in FIG. 8, the depth from the first surface 10a of the semiconductor substrate 10 to the position where the impurity concentration of the stabilization layer 19 is at its maximum is indicated as the peak position of the stabilization layer 19. Furthermore, in FIG. 8, the depth from the first surface 10a of the semiconductor substrate 10 to the second peak position P2 of the second base layer 12b is set to 0.86 μm. A peak position of zero for the stabilization layer 19 in FIG. 8 means that the stabilization layer 19 has not been formed.

As shown in FIG. 8, it is confirmed that the threshold voltage Vth remains almost unchanged if the peak position, where the impurity concentration of the stabilization layer 19 is at its maximum, is 0.5 μm or less. That is, it has been confirmed that the threshold voltage Vth does not change if the depth from the first surface 10a of the semiconductor substrate 10 to the peak position where the impurity concentration of the stabilization layer 19 is at its maximum is 58% or less of the depth from the first surface 10a of the semiconductor substrate 10 to the second peak position P2 of the second base layer 12b. Therefore, it is preferable that the stabilization layer 19 be formed so that the depth from the first surface 10a of the semiconductor substrate 10 to the peak position where the impurity concentration of the stabilization layer 19 is at its maximum is 58% or less of the depth from the first surface 10a of the semiconductor substrate 10 to the second peak position P2 of the second base layer 12b.

According to the above-described embodiment, the FWD region 2 is configured such that the first surface 10a of the semiconductor substrate 10, which is connected to the upper electrode 22, includes the stabilization layer 19 of N-type. Therefore, effects similar to those of the first embodiment can be obtained.

In the present embodiment, the stabilization layer 19 is also disposed in the IGBT region 1, and the impurity concentration of the stabilization layer 19 is lower than that of the contact region 18. Therefore, the stabilization layer 19 can be formed by implanting N-type impurity ions without placing a mask, thereby simplifying the manufacturing process.

In the present embodiment, by setting the surface concentration of the stabilization layer 19 lower than that of the emitter region 17, it is possible to suppress a reduction in latch-up tolerance.

In the present embodiment, by forming the stabilization layer 19 so that the depth of the peak position of the stabilization layer 19 is less than or equal to 58% of the depth from the first surface 10a of the semiconductor substrate 10 to the second peak position P2 of the second base layer 12b, it is possible to suppress variations in the threshold voltage Vth.

### Other Embodiments

Although the present disclosure has been described in accordance with the embodiments, it is understood that the present disclosure is not limited to such embodiments or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

For example, in each of the above-described embodiments, the first conductive type is N-type and the second conductive type is P-type. Alternatively, the first conductive type may be P-type and the second conductive type may be N-type. In each of the above-described embodiments, the trench gate structure does not necessarily have to be formed in the FWD region 2.

In each of the above-described embodiments, an example has been described in which the first surface 10a of the semiconductor substrate 10 in the FWD region 2 is composed of the contact region 18 and the stabilization layer 19. However, the stabilization layer 19 may be formed in a part of the surface portion of the second base layer 12b, so that the second base layer 12b is exposed at the first surface 10a of the semiconductor substrate 10. Even with such a semiconductor device, compared to a case where the first surface 10a of the semiconductor substrate 10 in the FWD region 2 is composed of the contact region 18 and the second base layer 12b, it is possible to reduce the proportion of the second base layer 12b, which is prone to impurity concentration variation, on the first surface 10a of the semiconductor substrate 10. Therefore, effects similar to those of the first embodiment can be obtained.

Similarly, in the second embodiment described above, an example has been described in which the first surface 10a of the semiconductor substrate 10 in the IGBT region 1 is composed of the emitter region 17, the contact region 18, and the stabilization layer 19. However, the stabilization layer 19 may be formed in a part of the surface portion of the second base layer 12b in the IGBT region 1, so that the second base layer 12b is exposed at the first surface 10a of the semiconductor substrate 10.

In addition, in the second embodiment described above, the surface concentration of the stabilization layer 19 may be higher than the surface concentration of the emitter region 17. The stabilization layer 19 may be formed so that the depth of the peak position of the stabilization layer 19 is greater than 58% of the depth of the second peak position P2 of the second base layer 12b. Even with such a semiconductor device, compared to a case where the first surface 10a of the semiconductor substrate 10 in the FWD region 2 is composed of the contact region 18 and the second base layer 12b, it is possible to reduce the proportion of the second base layer 12b, which is prone to impurity concentration variation, on the first surface 10a of the semiconductor substrate 10. Therefore, effects similar to those of the first embodiment can be obtained.

What is claimed is:

1. A semiconductor device comprising:
a semiconductor substrate having an insulated gate bipolar transistor (IGBT) region including an IGBT element and a freewheeling diode (FWD) region including an FWD element, the semiconductor substrate including a drift layer of a first conductivity type, a base layer of a second conductivity type disposed above the drift layer, a collector layer of the second conductivity type disposed on a side of the drift layer opposite the base layer in the IGBT region, and a cathode layer of the first conductivity type disposed on the side of the drift layer opposite the base layer in the FWD region, the semiconductor substrate having a first surface adjacent to the base layer and a second surface adjacent to the collector layer and the cathode layer;
a barrier region of the first conductivity type disposed within the base layer and dividing the base layer into a first base layer adjacent to the drift layer and a second base layer adjacent to the first surface of the semiconductor substrate;
a trench gate structure including a trench penetrating the base layer and the barrier region into the drift layer in the IGBT region, a gate insulating film disposed on a wall surface of the trench, and a gate electrode disposed on the gate insulating film;
an emitter region of the first conductivity type disposed in a surface portion of the second base layer in the IGBT region and in contact with the trench;
a contact region of the second conductivity type disposed in the surface portion of the second base layer in the FWD region and having a higher impurity concentration than the second base layer;
a stabilization layer of the first conductivity type disposed, together with the contact region, in the surface portion of the second base layer in the FWD region;
a first electrode disposed on the first surface of the semiconductor substrate and electrically connected to the emitter region and the contact region; and
a second electrode disposed on the second surface of the semiconductor substrate and electrically connected to the collector layer and the cathode layer, wherein
the base layer is an ion-implanted layer,
the second base layer has a peak position, where an impurity concentration of the second base layer is maximum, at a depth between the emitter region and the barrier region and different from both a boundary with the emitter region and a boundary with the barrier region,
the first electrode is electrically connected to the contact region and the stabilization layer in the FWD region, and
the stabilization layer has a lower impurity concentration than the emitter region.

2. The semiconductor device according to claim 1, wherein
in the FWD region, the stabilization layer is disposed over an entire region of the first surface of the semiconductor substrate except for a region where the contact region is disposed.

3. The semiconductor device according to claim 1, wherein
the stabilization layer is also disposed in the surface portion of the second base layer in the IGBT region.

4. The semiconductor device according to claim 1, wherein
the contact region is also disposed in the surface portion of the second base layer in the IGBT region, and
in the FWD region, the stabilization layer is disposed over an entire region of the first surface of the semiconductor substrate except for a region where the contact region is disposed,
in the IGBT region, the stabilization layer is disposed over an entire region of the first surface of the semiconductor substrate except for regions where the emitter region and the contact region are disposed, and
the stabilization layer has a lower impurity concentration than the contact region.

5. The semiconductor device according to claim 3, wherein
in the IGBT region, a depth from the first surface of the semiconductor substrate to a position where an impurity concentration of the stabilization layer is maximum is set to be less than or equal to 58% of a depth from the first surface of the semiconductor substrate to the peak position where the impurity concentration of the second base layer is maximum.
